(19) United States
(12) Patent Application Publication
(10) Pub. No.: US 2026/0358715 A1
(43) Pub. Date: Nov. 12, 2026

(54) METHOD FOR ADJUSTMENT OF AN ILLUMINATION SYSTEM OF A PROJECTION EXPOSURE APPARATUS, AND ILLUMINATION SYSTEM FOR CARRYING OUT THE METHOD

(71) Applicant: Carl Zeiss SMT GmbH, Oberkochen (DE)

(72) Inventors: Stefan LIPPOLDT, Aalen (DE); Stig BIELING, Aalen (DE); Harald LOSERT, Ulm (DE)

(21) Appl. No.: 19/670,884

(22) Filed: May 7, 2026

Related U.S. Application Data
(63) Continuation of application No. PCT/EP2024/081174, filed on Nov. 5, 2024.

(30) Foreign Application Priority Data
Nov. 10, 2023 (DE) 10 2023 211 120.9

(51) Int. Cl. G03F 7/00; G02B 5/00; G02B 26/08

(52) U.S. Cl. CPC G03F 7/70141; G02B 5/001; G02B 26/08; G03F 7/70108; G03F 7/70525; G03F 7/7085

(57) ABSTRACT

For adjustment of an illumination system of a projection exposure apparatus, the illumination system has a light source and an illumination optical unit. Firstly, a maximum object field illumination angle to be set is predefined, at which angle an object field, in which an object to be imaged is arrangeable, is illuminated via the illumination optical unit. A distance between axicon elements of an axicon module of the illumination optical unit is set in order to predefine a raw object field illumination angle, which is different than the maximum object field illumination angle to be set. The light source, which generates illumination light, is adjusted along an optical axis of the illumination optical unit until, proceeding from the predefined raw object field illumination angle, the maximum object field illumination angle to be set is attained.

### CROSS-REFERENCE TO RELATED APPLICATIONS

The present application is a continuation of, and claims benefit under 35 USC 120 to, international application No. PCT/EP 2024/081174, filed Nov. 5, 2024, which claims benefit under 35 USC 119 of German Application No. 10 2023 211 120.9, filed Nov. 10, 2023. The entire disclosure of each of these applications is incorporated by reference herein.

### FIELD

The disclosure relates to a method for adjustment of an illumination system of a projection exposure apparatus. Furthermore, the disclosure relates to an illumination system for carrying out such a method, an optical system comprising such an illumination system, a projection exposure apparatus comprising such an optical system, a method for producing a microstructured or nanostructured component using such a projection exposure apparatus, and a structured component, produced by such a method.

### BACKGROUND

An illumination system is known from WO 2005/015 310 A2, DE 10 2004 059 493 A1, and WO 2016/188 739 A1. US 2014/0043594 A1 likewise discloses an illumination system.

### SUMMARY

The present disclosure seeks to develop an adjustment method for adjustment or for preparing an adjustment of an illumination system to improve transmission of the illumination system, i.e. in an illumination light throughput, for a maximum object field illumination angle to be set.

In a first aspect, the disclosure provides a method for adjusting an illumination system of a projection exposure apparatus. The projection exposure apparatus comprises a light source for generating illumination light; an illumination optical unit for guiding the illumination light toward an object field, in which an object to be imaged is arrangeable, the illumination optical unit comprising an axicon module comprising two axicon elements, the distance between which is settable in order to predefine a maximum object field illumination angle within an illumination angle range. The light source is adjustable along an optical axis of the illumination optical unit. The method comprises: predefining a maximum object field illumination angle to be set; setting a distance between the axicon elements in order to predefine a raw object field illumination angle, which is different than the maximum object field illumination angle to be set; adjusting the light source along the optical axis of the illumination optical unit until, proceeding from the predefined raw object field illumination angle, the maximum object field illumination angle to be set is attained.

According to the disclosure, it has been recognized that for optimizing the transmission for a given maximum object field illumination angle to be set, it is desirable for initially during the setting of the axicon module what to be predefined by the axicon distance setting is not the maximum object field illumination angle actually to be set, but rather a raw object field illumination angle different than that. During a subsequent axial adjusting of the light source, in the context of the adjustment method, from the raw object field illumination angle initially set, the maximum object field illumination angle actually to be set can then be set according to the original predefinition of the adjustment method. Given an optimum choice of the raw object field illumination angle, the outcome can therefore be the maximum transmission for the predefined maximum object field illumination angle. This adjustment method can make use of the fact that an axial adjusting of the light source also influences the maximum object field illumination angle of the illumination system. Certain undesirable features of a method in which the distances between the axicon elements are set such that the predefined maximum object field illumination angle is attained when the light source is subsequently adjusted in order to maximize the transmission, for example transmission losses, can be avoided.

The adjustment method can be carried out at least partly by way of a simulation method. Simulated method results can then be verified at least partly by checking on a real illumination system. If this verification reveals that the simulation sufficiently accords with reality, a complete adjustment of the illumination system according to the adjustment method can then take place.

The axicon module can be embodied as a zoomable system. The axicon module can have at least one displaceable optical component, for example a displaceable lens element, which sets an imaging scale between a first plane disposed upstream of the axicon module in the beam path of the illumination light and a second plane disposed downstream of the axicon module in the beam path of the illumination light. The object field illumination angle, for example, can be predefined by this approach. The axicon module can be embodied as a zoomable axicon together with a zoom optical unit that sets the imaging scale.

In an adjustment method according to the disclosure, an upstream two-dimensional optimization or calibration can take place, in which for each combination of setting values “distance between the axicon elements”, firstly, and “light source position”, secondly, both a maximum object field illumination angle established and a resultant transmission of the illumination system are captured, which can be done by simulation and/or by measurement. The result of this two-dimensional optimization can then be an assignment of object field illumination angles with in each case maximum transmission and the parameters to be set therefor: “distance between the axicon elements”, firstly, and “light source position”, secondly. In the context of operation of the projection exposure apparatus with an illumination system calibrated in this way, following predefinition of the maximum object field illumination angle to be set it can then be possible to set that parameter combination “distance between the axicon elements” and “light source position” which results in firstly this maximum object field illumination angle and secondly a maximum transmission.

In embodiments, a maximum transmission of the illumination optical unit is attained in the case of a pre-optimization in the case of a predefined maximum transmission object field illumination angle, and, in the case of the maximum object field illumination angle which is to be set in the context of the adjustment and which is less than the maximum transmission object field illumination angle, when setting the distance, a raw object field illumination angle is predefined which is greater than the maximum object field illumination angle to be set. In embodiments, a maximum transmission of the illumination optical unit is attained in the case of a pre-optimization in the case of a predefined maximum transmission object field illumination angle, and, in the case of the maximum object field illumination angle which is to be set in the context of the adjustment and which is greater than the maximum transmission object field illumination angle, when setting the distance between the axicon elements, a raw object field illumination angle is predefined which is less than the maximum object field illumination angle to be set. Such embodiments can lead to a correspondingly improved transmission result depending on whether the maximum object field illumination angle to be set is less than or greater than the maximum transmission object field illumination angle that is ascertainable in the context of the pre-optimization. It has been found here that it can be desirable for the adjustment specification to be adapted accordingly depending on whether the maximum object field illumination angle to be set is less than or greater than the maximum transmission object field illumination angle.

In a second aspect, the disclosure provides an illumination system configured to carry out a method for adjusting an illumination system of a projection exposure apparatus according to the disclosure. The illumination system comprises: a light source for generating illumination light; and an illumination optical unit for guiding the illumination light toward an object field, in which an object to be imaged is arrangeable. The illumination optical unit has an axicon module comprising two axicon elements. The distance between the two axicon elements is settable via an axicon adjusting drive in order to predefine a maximum object field illumination angle within an illumination angle range. The light source is adjustable along an optical axis of the illumination optical unit via a light source adjusting drive. The illumination system further comprises an open-loop/closed-loop control device signal-connected to the axicon adjusting drive and the light source adjusting drive.

Features of the second aspect can correspond to those explained above with reference to the first aspect. The open-loop/closed-loop control device can help enable open-loop-and/or closed-loop-controlled operation of the illumination system for setting the object field illumination angle with at the same time optimized transmission of the illumination system.

In embodiments, an illumination system further comprises a transmission sensor for measuring an actual transmission of the illumination optical unit in an illumination light beam path section between the light source and the object field. The transmission sensor is signal-connected to the open-loop/closed-loop control device. Such a transmission sensor can enable an automatic optimization of the transmission of the illumination system or a closed-loop control of the system to a predefined setpoint transmission.

In embodiments, an illumination system further comprises an illumination angle sensor for measuring a maximum actual object field illumination angle. The illumination angle sensor is signal-connected to the open-loop/closed-loop control device. Such an illumination angle sensor can help enable, for example, a closed-loop control to a maximum setpoint object field illumination angle. The illumination angle sensor can be a sensor for capturing a pupil illumination in an illumination pupil. Such a pupil sensor is known for example from DE 10 2018 207 384 B4.

In addition, the illumination system can have a sensor for capturing a uniformity of an object field illumination and/or an image field illumination, i.e. for capturing an intensity of an illumination of the respective field, in a manner spatially resolved over the field. A deviation of an actual illumination homogeneity from a setpoint illumination homogeneity over the field respectively illuminated can be captured by such a uniformity sensor. For the specification of this illumination parameter “uniformity”, reference is made to EP 0 952 491 A2 and the references indicated there. In addition, the illumination system can have a telecentricity sensor for capturing an illumination telecentricity error. For the definition of this measurement variable “telecentricity error”, reference is made to DE 10 2009 045 491 A1. In addition, the illumination system can have an ellipticity sensor for capturing an illumination ellipticity of the illumination system. For the definition of the illumination parameter “ellipticity”, reference is made to U.S. Pat. No. 9,625,827 B2. By this approach, it is possible to capture further actual parameters for which an open-loop-controlled predefinition or else a closed-loop control to corresponding parameter setpoint values is made possible in the context of an adjusting of the axicon module and/or the light source by way of the respective adjusting drives.

In a third aspect, the disclosure provides an optical system comprising an illumination system according to the disclosure and an imaging optical unit for imaging the object field into an image field, in which a section of a substrate is arrangeable.

In a fourth aspect, the disclosure provides a projection exposure apparatus comprising an illumination system according to the disclosure and an imaging optical unit for imaging the object field into an image field, in which a section of a substrate is arrangeable.

In a fifth aspect, the disclosure provides a method for producing structured components. The method comprises: providing a wafer, on which a layer composed of a light-sensitive material is at least partly applied; providing a reticle having structures to be imaged; providing a projection exposure apparatus according to the disclosure; and projecting at least one part of the reticle onto a region of the layer of the wafer with the aid of the projection exposure apparatus.

In a sixth aspect, the disclosure provides a structured component which is produced according to a production method according to the disclosure.

Certain features of the third, fourth, fifth and/or sixth aspects can correspond the first and/or second aspects.

The light source of an illumination system can be a mercury-vapor lamp, an excimer laser or an LED light source.

A structured element, such as a microchip, for example a memory chip, can be produced according to the disclosure.

### BRIEF DESCRIPTION OF THE DRAWINGS

Exemplary embodiments of the disclosure are explained in greater detail below with reference to the drawing, in which:

FIG. 1 shows a meridional section through optical main groups of a microlithographic projection exposure apparatus;

FIG. 2 shows a diagram of a transmission of an optical system of the projection exposure apparatus as a function of a maximum object field illumination angle to be set, parameterized by a pupil radius σ₉₀ encompassing 90% of an illumination energy which is radiated into an illumination pupil at this maximum object field illumination angle to be set; and

FIG. 3 shows, once again as a function of the illumination angle parameter σ₉₀, a relative gain in transmission upon comparison of two different adjustment methods for an illumination system which is part of the optical system of the projection exposure apparatus.

### DETAILED DESCRIPTION

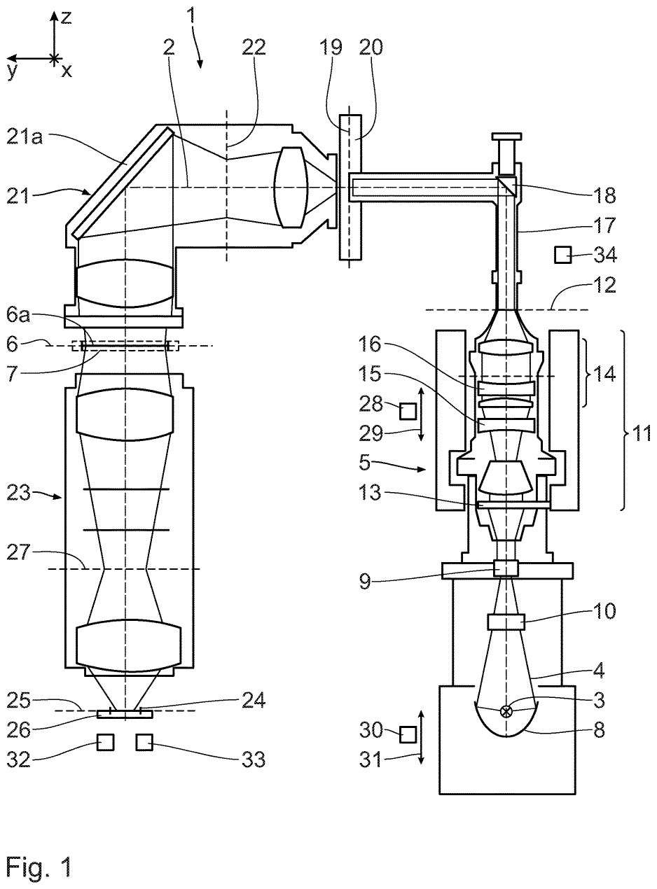

A projection exposure apparatus 1 is illustrated in meridional section in FIG. 1 as regards its optical main groups.

In order to facilitate the illustration of positional relationships, an xyz coordinate system will be used below. In FIG. 1, the x-axis extends into the plane of the drawing perpendicularly in relation thereto. The y-axis extends toward the left in FIG. 1. The z-axis extends upward in FIG. 1.

An optical axis 2 extending through an entire optical system of the projection exposure apparatus 1, proceeding from a light source 3, is indicated in a dashed manner in FIG. 1. This optical axis 2 is folded a number of times by 90° in each case in the embodiment of the projection exposure apparatus 1 illustrated in FIG. 1. Such foldings can also be designed differently or optionally even be entirely dispensed with.

The light or radiation source 3 of the projection exposure apparatus 1 generates used light in the form of an illumination or imaging beam 4, which is illustrated by marginal rays in FIG. 1. The used light 4 is also referred to as illumination light or as imaging light. The used light 4 has a wavelength in the deep ultraviolet (DUV) range, for example in the range between 100 nm and 200 nm, or in the ultraviolet (UV) range between 200 nm and 400 nm. Alternatively, the used light 4 can also have a wavelength in the extreme ultraviolet (EUV) range, for example between 5 nm and 30 nm. Exemplary wavelengths of the beam source 3 are 365 nm, 248 nm or 193 nm. Depending on the radiation source 3 used, a used wavelength spectrum utilized is narrowband, but can also have a greater broadband capacity, for example if an Hg discharge lamp is utilized.

An illumination optical unit 5 of the projection exposure apparatus 1 guides the used light 4 from the radiation source 3 toward an object plane 6 of the projection exposure apparatus 1. Together with the light source 3, the illumination optical unit 5 forms an illumination system of the projection exposure apparatus. An object, which is in the form of a reticle 7 and is to be imaged by the projection exposure apparatus 1, is arranged in the object plane 6. The reticle 7 is illustrated in a dashed manner in FIG. 1. The reticle 7 is carried by a holder, not illustrated, which enables a controlled scan displacement or step-by-step displacement. It is possible to use a transmissive reticle, as illustrated in FIG. 1, but also a reflective reticle, depending on the embodiment of the projection exposure apparatus 1. The reticle 7 is arranged in an object field 6a in the object plane 6.

A collector 8 in the form of an ellipsoidal mirror transfers the illumination light 4 emanating from a source region of the light source 3 into an intermediate focus 9. A shutter is arranged there for the controlled release of the illumination light 4 toward the optical system components that follow along the optical axis 2. There is also a safety shutter 10 arranged upstream of this intermediate focus shutter in the beam path of the illumination light 4.

A pupil shaping optical unit 11 of the illumination optical unit 5 is disposed downstream of the intermediate focus 9 in the beam path of the illumination light 4. The pupil shaping optical unit 11 serves to generate a defined intensity distribution of the illumination light 4 in a downstream pupil plane of the illumination system. The pupil shaping optical unit 11 additionally serves as a setting device for predefining various illumination settings or various illumination settings with different maximum object field illumination angles. An image of the light source at the intermediate focus 9 is imaged into a pupil plane 12 of the illumination optical unit 5 by the pupil shaping optical unit 11. The pupil shaping optical unit 11 includes an interference filter 13 and, disposed downstream thereof, an axicon module 14 comprising two axicon elements 15, 16. The axicon module 14 makes it possible to predefine a maximum object field illumination angle for illuminating the object field 6a in a settable manner within an illumination angle range.

As a measure of the maximum object field illumination angle set in each case by way of the pupil shaping optical unit 11, use is made of a pupil radius σ₉₀, which indicates for a specific pupil illumination of the pupil plane 12 or a downstream pupil plane of the illumination optical unit 5 the radius which encompasses 90% of an illumination light energy radiated into this pupil plane. σ₉₀ is indicated in relative pupil coordinates. In this case, the value “σ₉₀=1” indicates that an edge of a maximally illuminable pupil of the illumination system has been reached.

Disposed downstream of the pupil plane 12 there is an illumination light mixing unit 17, which can be an optical rod, for example a rod having a hexagonal or rectangular cross section. A plurality of rod sections disposed one after another can also form the illumination light mixing unit 17. An entrance plane of the optical rod of the illumination light mixing unit 17 can coincide with the pupil plane 12.

In the region of the illumination light mixing unit 17, an illumination light beam path is deflected by 90° via a folding mirror 18, such that the optical axis 2 from then on no longer extends along the positive z-direction, but rather along the positive y-direction of the xyz-coordinate system in FIG. 1. An intermediate field plane 19 of the illumination optical unit 5 is present where the illumination light 4 exits from the illumination light mixing unit 17. A stop 20 for predefining a marginal boundary of the object field 6a lies in this intermediate field plane 19. The stop 20 is also referred to as a REMA stop (reticle masking system for stopping down the reticle 7).

The intermediate field plane 19 is imaged into the object plane 6 by an imaging optical unit 21, which is also referred to as a REMA lens. The imaging optical unit 21 includes a 90° folding mirror 21 a, such that the optical axis 2, which up to that point has extended along the positive y-direction, now extends in the negative z-direction. A further pupil plane 22 lies between the field planes 19 and 6.

The object field 6a is imaged into an image field 24 in an image plane 25 via a projection optical unit 23. In the image plane 25, a wafer 26 is arranged in the region of the image field 24. The wafer is carried by a holder, not illustrated, which enables a controlled scan displacement of the wafer 26 or else a step-by-step displacement of the wafer 26.

Together with the illumination optical unit 5, the projection optical unit 23 forms an optical system of the projection exposure apparatus 1.

A pupil plane 27 of the projection optical unit 23 lies between the object plane 6 and the image plane 25. An aperture stop for marginally predefining a pupil of the projection optical unit 23 can be arranged in the pupil plane 27.

A distance between the two axicon elements 15, 16 is predefined in order to predefine the maximum object field illumination angle by way of an axicon actuator 28, which is illustrated schematically in FIG. 1. The axicon actuator 28 is mechanically connected to the axicon element 15 and/or to the axicon element 16, such that at least one of these axicon elements 15, 16 is displaceable along the z-direction, i.e. along the optical axis, as indicated by a double-headed arrow 29 in FIG. 1. Both axicon elements 15, 16 can also be displaceable, for example to different extents, along the z-direction via the axicon actuator 28. The axicon actuator 28 constitutes an axicon adjusting drive. An absolute value of a maximum object field illumination angle, i.e. the pupil radius σ₉₀, is dependent on the z-positions of the axicon elements 15, 16.

Furthermore, the light source 3 is adjustable by way of a light source actuator 30 in turn along the z-axis in FIG. 1, i.e. along the optical axis 2, as is illustrated via a double-headed arrow 31 in FIG. 1. The light source actuator 30 constitutes a light source adjusting drive.

Both a respective z-distance position of the two axicon elements 15, 16 relative to one another, set by way of the axicon actuator 28, and a z-position of the light source 3, set by way of the light source actuator 30, influence a pose of an imaging of the intermediate focus 9 in the region of the pupil plane 12, i.e. in the region of an entrance into the illumination light mixing unit 17. At the same time, a z-displacement of the light source 3 influences an absolute value of the maximum object field illumination angle in the case where the positioning of the axicon module 14 is unchanged.

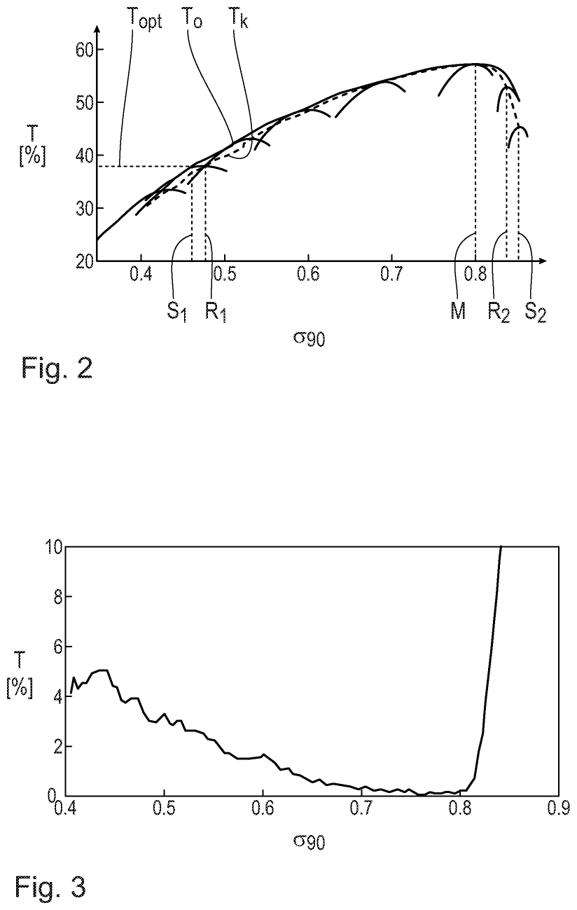

These dependencies are used during an adjustment-described below-of the illumination system of the projection exposure apparatus with the aim of a throughput-or transmission-optimized predefinition of a maximum object field illumination angle to be set. This is described below with the aid of FIG. 2, which illustrates a transmission T of the illumination system as a function of a respective maximum object field illumination angle σ₉₀.

During this illumination system adjustment, firstly the maximum object field illumination angle to be set is predefined. This can be for example a maximum object field illumination angle σ₉₀ of 0.45, as illustrated in a dashed manner at S₁ on the left in FIG. 2.

Following the predefinition of this maximum object field illumination angle to be set as a setpoint value S, a distance between the axicon elements 15, 16 is set via the axicon actuator 28 in order to predefine a raw object field illumination angle R, which is different than the maximum object field illumination angle S to be set. In the example illustrated on the left in FIG. 2, the raw object field illumination angle R₁ has a value of approximately σ₉₀=0.47.

After that, using the light source actuator 30, the light source 3 is adjusted along the optical axis 2 of the illumination optical unit 5 until the maximum object field illumination angle S to be set is attained. This results in an optimized transmission value Tₒₚₜ of approximately 38%. This transmission value Tₒₚₜ, as revealed by comparison adjustments, is greater than a transmission value that arises in an alternative adjustment method, wherein the distances between the axicon elements 15, 16 are set by way of the axicon actuator 28 such that, without using as a basis a raw object field illumination angle R which is different than the maximum object field illumination angle S, following the setting of the maximum object field illumination angle S, the light source 3 is subsequently adjusted by way of the light source actuator 30 in order to maximize the transmission. By way of this alternative adjustment method, which is also referred to as conventional setting, regularly only a secondary optimum of the transmission is attained, rather than the transmission value Tₒₚₜ of approximately 38% that is attained by way of the method described first above.

FIG. 2 clarifies the attainable transmission differences between this method described first, wherein firstly the raw object field illumination angle R is predefined via the axicon actuator 28, and an alternative adjustment method, which is not as good with regard to the attainable transmission.

A transmission curve Tₒ shows the profile of an optimum transmission versus the maximum object field illumination angle σ₉₀, attained by way of the method described first with a raw object field illumination angle R initially set via the axicon actuator 28. In contrast thereto, the dashed transmission curve Tₖ shows an attainable maximum transmission, once again as a function of the maximum object field illumination angle σ₉₀, attained by way of the conventional setting.

Both curves Tₒ and Tₖ clarify that in the case of a specific predefined maximum transmission object field illumination angle M of approximately σ₉₀=0.8, overall a maximum transmission of the illumination optical unit 5 in the region of not quite 60% is attained. This object field illumination angle M with the maximum transmission can be ascertained in the context of a pre-optimization of the illumination system.

Insofar as a maximum object field illumination angle S which is less than this maximum transmission object field illumination angle M is intended to be set in the context of the adjustment, firstly, as already explained above with reference to the examples S₁ =0.45 and R₁=0.47, a raw object field illumination angle R which is greater than the object field illumination angle S to be set, for example R=0.84, is predefined in the context of the adjustment method. In this case, S<R<M thus holds true.

Insofar as a maximum object field illumination angle S which is greater than the object field illumination angle M, for example a maximum object field illumination angle S₂=0.85, is intended to be set in the context of the adjustment, a raw object field illumination angle R₂ which is less than the maximum object field illumination angle S₂ to be set is predefined in the context of the adjustment when initially setting the distance between the axicon elements 15, 16 via the axicon actuator 28. This is illustrated on the right-hand side in FIG. 2. In this case, M<R<S holds true.

FIG. 3 clarifies a relative gain in transmission that can be attained by way of the method comprising the intermediate step of the raw object field illumination angle in comparison with the conventional method, i.e. illustrates a relative gain in transmission by comparison of the curves Tₒ and Tₖ according to FIG. 2. The relative gain in transmission is the smallest in the region of σ₉₀=M. Toward larger illumination angles (σ₉₀>0.8) the relative gain in transmission increases greatly. Toward smaller object field illumination angles (0.4≤σ₉₀≤0.65) as well, a relative gain in transmission arises which is all the greater, the smaller the maximum object field angle σ₉₀.

The illumination system of the projection exposure apparatus 1 furthermore has a transmission sensor 32 for measuring an actual transmission of the optical system and for example of the illumination optical unit 5 in an illumination light beam path section between the light source 3 and the object field 6a. This transmission sensor 32 can have at least one photodiode that is sensitive to the illumination light 4. The transmission sensor 32 can be arranged in the region of the image plane 25. The transmission sensor 32 can alternatively be arranged at a suitable location in the beam path of the illumination light 4 in the region of the object field 6a or can be arranged in the beam path of an illumination light reflection that is not used otherwise.

Furthermore, the illumination system has an illumination angle sensor 33 for measuring a maximum actual object field illumination angle. Such an illumination angle sensor can be designed in the manner of a sensor disposed downstream of an image plane, as described in DE 10 2018 207 384 B4. Alternatively or additionally, such an illumination angle sensor can also measure a maximum object field illumination angle actually in the region of the object field 6a, i.e. in the region of the object plane 6.

The transmission sensor 32 and the illumination angle sensor 33 are signal-connected to an open-loop/closed-loop control device 34 of the projection exposure apparatus 1. Furthermore, the axicon actuator 28 and the light source actuator 30 are signal-connected to this open-loop/closed-loop control device 34.

The adjustment method can be operated inline. Alternatively, the adjustment method can also include a prior calibration, wherein the transmission is a maximum and wherein the illumination system of the projection exposure apparatus is simulated beforehand and is set in a targeted manner subsequently on the basis of the simulation results. Such a simulation takes place in an at least two-dimensional parameter space, i.e. firstly a distance position of the axicon elements 15, 16 and secondly a light source position. For the respective parameter pair “distance between the axicon elements” and “light source position”, a resulting object field illumination angle and a resulting transmission of the illumination system are ascertained and logged, for example stored in a table. For each given object field illumination angle, a parameter pair for which the transmission is a maximum can then be determined and in turn logged and for example recorded in a tabular fashion. A resulting table then records, for each object field illumination angle within a used range of maximum object field illumination angles to be set, what parameters “distance between the axicon elements” and “light source position” are to be set in order that the maximum transmission of the illumination system results for this object field illumination angle. In order to set a predefined object field illumination angle, the parameters “distance between the axicon elements” and “light source position” logged or tabulated for this purpose are then set up. The maximally attainable transmission of the illumination system then results for this predefined object field illumination angle.

In the calibration method, therefore, within predefined distance values and light source position values for each parameter combination “distance between the axicon elements” and “light source position” the resulting object field illumination angle and the resulting transmission are captured. This can be done by way of a simulation and/or by way of a measurement. That parameter combination for which a maximum transmission is present is then determined for each value of an object field illumination angle. If an object field illumination angle to be set is predefined subsequently during operation of the projection exposure apparatus with the calibrated illumination system, that parameter combination “distance between the axicon elements”, firstly, and “light source position”, secondly, is set which gives rise to this maximum transmission ascertained during the calibration.

Following the corresponding predefinition of an illumination setting, for example a maximum object field illumination angle, and subsequent transmission optimization with the aid of the adjustment method described, at least one part of the reticle 7 is imaged, with the aid of the projection exposure apparatus 1, onto a region of a light-sensitive layer on the wafer 26 in order to lithographically produce a micro-or nanostructured component. Depending on the embodiment of the projection exposure apparatus 1 as a scanner or as a stepper, the reticle 7 and the wafer 26 are moved in a temporally synchronized manner in the y-direction continuously in scanner operation or step by step in stepper operation.

What is claimed is:

1. A method of adjusting an illumination system of a projection exposure apparatus, the projection exposure apparatus comprising a light source for generating illumination light and an illumination optical unit for guiding the illumination light toward an object field, the illumination optical unit comprising an axicon module, the axicon module comprising first and second axicon elements, a distance between the first and second axicon elements being settable to predefine a maximum object field illumination angle within an illumination angle range, the light source being adjustable along an optical axis of the illumination optical unit, the method comprising:
predefining a maximum object field illumination angle;
setting the distance between the first and second axicon elements to predefine a raw object field illumination angle which is different from the maximum object field illumination angle; and
adjusting the light source along the optical axis of the illumination optical unit until, proceeding from the predefined raw object field illumination angle, the maximum object field illumination angle is attained.

2. The method of claim 1, wherein:
a maximum transmission of the illumination optical unit is attained in the case of a pre-optimization in the case of a predefined maximum transmission object field illumination angle; and
when the maximum object field illumination angle is less than the maximum transmission object field illumination angle, when setting the distance between the first and second axicon elements, predefining a raw object field illumination angle which is greater than the maximum object field illumination angle.

3. The method of claim 1, wherein:
a maximum transmission of the illumination optical unit is attained in the case of a pre-optimization in the case of a predefined maximum transmission object field illumination angle; and
when the maximum object field illumination angle is greater than the maximum transmission object field illumination angle, when setting the distance between the first and second axicon elements, predefining a raw object field illumination angle which is less than the maximum object field illumination angle.

4. The method of claim 3, wherein, when the maximum object field illumination angle is less than the maximum transmission object field illumination angle, when setting the distance between the first and second axicon elements, predefining a raw object field illumination angle which is greater than the maximum object field illumination angle.

5. An illumination system, comprising:
a light source configured to generate illumination light, the light source being adjustable along an optical axis of the illumination optical unit via a light source adjusting drive;
an illumination optical unit configured to guide the illumination light toward an object field, the illumination optical unit comprising an axicon module, the axicon module comprising first and second axicon elements, a distance between the first and second axicon elements being settable via an axicon adjusting drive to predefine a maximum object field illumination angle within an illumination angle range; and
an open-loop/closed-loop control device signal-connected to the axicon adjusting drive and the light source adjusting drive so that, during use of the illumination system, the open-loop/closed-loop control controls the illumination system to:
predefine a maximum object field illumination angle;
set the distance between the first and second axicon elements to predefine a raw object field illumination angle which is different from the maximum object field illumination angle; and
adjust the light source along the optical axis of the illumination optical unit until, proceeding from the predefined raw object field illumination angle, the maximum object field illumination angle is attained.

6. The illumination system of claim 5, further comprising a transmission sensor configured to measure an actual transmission of the illumination optical unit in an illumination light beam path section between the light source and the object field, wherein the transmission sensor is signal-connected to the open-loop/closed-loop control device.

7. The illumination system of claim 6, further comprising an illumination angle sensor configured to measure the maximum actual object field illumination angle, wherein the illumination angle sensor is signal-connected to the open-loop/closed-loop control device.

8. The illumination system of claim 5, further comprising an illumination angle sensor configured to measure the maximum actual object field illumination angle, wherein the illumination angle sensor is signal-connected to the open-loop/closed-loop control device.

9. An optical system, comprising:
an illumination system according to claim 4; and
an imaging optical unit configured to image the object field into an image field.

10. An optical system, comprising:
an illumination system according to claim 5; and
an imaging optical unit configured to image the object field into an image field,
wherein the illumination system further comprises a transmission sensor configured to measure an actual transmission of the illumination optical unit in an illumination light beam path section between the light source and the object field, and the transmission sensor is signal-connected to the open-loop/closed-loop control device.

11. An optical system, comprising:
an illumination system according to claim 5; and
an imaging optical unit configured to image the object field into an image field,
wherein the illumination system further comprises a transmission sensor configured to measure an actual transmission of the illumination optical unit in an illumination light beam path section between the light source and the object field, and the transmission sensor is signal-connected to the open-loop/closed-loop control device, and
wherein the illumination system further comprises an illumination angle sensor configured to measure the maximum actual object field illumination angle, and the illumination angle sensor is signal-connected to the open-loop/closed-loop control device.

12. An optical system, comprising:
an illumination system according to claim 5; and
an imaging optical unit configured to image the object field into an image field,
wherein the illumination system further comprises an illumination angle sensor configured to measure the maximum actual object field illumination angle, and the illumination angle sensor is signal-connected to the open-loop/closed-loop control device.

13. An apparatus, comprising:
an illumination system according to claim 5; and
an imaging optical unit configured to image the object field into an image field,
wherein the apparatus is a projection exposure apparatus.

14. An apparatus, comprising:
an illumination system according to claim 5; and
an imaging optical unit configured to image the object field into an image field,
wherein the apparatus is a projection exposure apparatus, and
wherein the illumination system further comprises a transmission sensor configured to measure an actual transmission of the illumination optical unit in an illumination light beam path section between the light source and the object field, and the transmission sensor is signal-connected to the open-loop/closed-loop control device.

15. An apparatus, comprising:
an illumination system according to claim 5; and
an imaging optical unit configured to image the object field into an image field,
wherein the apparatus is a projection exposure apparatus,
wherein the illumination system further comprises a transmission sensor configured to measure an actual transmission of the illumination optical unit in an illumination light beam path section between the light source and the object field, and the transmission sensor is signal-connected to the open-loop/closed-loop control device, and
wherein the illumination system further comprises an illumination angle sensor configured to measure the maximum actual object field illumination angle, and the illumination angle sensor is signal-connected to the open-loop/closed-loop control device.

16. An apparatus, comprising:
an illumination system according to claim 5; and
an imaging optical unit configured to image the object field into an image field,
wherein the apparatus is a projection exposure apparatus, and
wherein the illumination system further comprises an illumination angle sensor configured to measure the maximum actual object field illumination angle, and the illumination angle sensor is signal-connected to the open-loop/closed-loop control device.

17. A method of using a projection exposure apparatus comprising an illumination system and an imaging optical unit, the method comprising:
using the illumination system to illuminate a reticle in an object field of an object plane of the imaging optical;
using the imaging optical unit to image the illuminated reticle onto a light-sensitive material of an object in an image field of an image plane of the imaging optical unit,
wherein the illumination system is an illumination system according to claim 5.

18. A method of using a projection exposure apparatus comprising an illumination system and an imaging optical unit, the method comprising:
using the illumination system to illuminate a reticle in an object field of an object plane of the imaging optical;
using the imaging optical unit to image the illuminated reticle onto a light-sensitive material of an object in an image field of an image plane of the imaging optical unit,
wherein the illumination system is an illumination system according to claim, and
wherein the illumination system further comprises a transmission sensor configured to measure an actual transmission of the illumination optical unit in an illumination light beam path section between the light source and the object field, and the transmission sensor is signal-connected to the open-loop/closed-loop control device.

19. A method of using a projection exposure apparatus comprising an illumination system and an imaging optical unit, the method comprising:
using the illumination system to illuminate a reticle in an object field of an object plane of the imaging optical;
using the imaging optical unit to image the illuminated reticle onto a light-sensitive material of an object in an image field of an image plane of the imaging optical unit,
wherein the illumination system is an illumination system according to claim 5,
wherein the illumination system further comprises a transmission sensor configured to measure an actual transmission of the illumination optical unit in an illumination light beam path section between the light source and the object field, and the transmission sensor is signal-connected to the open-loop/closed-loop control device, and
wherein the illumination system further comprises an illumination angle sensor configured to measure the maximum actual object field illumination angle, and the illumination angle sensor is signal-connected to the open-loop/closed-loop control device.

20. A method of using a projection exposure apparatus comprising an illumination system and an imaging optical unit, the method comprising:
using the illumination system to illuminate a reticle in an object field of an object plane of the imaging optical;
using the imaging optical unit to image the illuminated reticle onto a light-sensitive material of an object in an image field of an image plane of the imaging optical unit,
wherein the illumination system is an illumination system according to claim 5, and
wherein the illumination system further comprises an illumination angle sensor configured to measure the maximum actual object field illumination angle, and the illumination angle sensor is signal-connected to the open-loop/closed-loop control device.
